(19) United States
(12) Patent Application Publication
(10) Pub. No.: US 2025/0308444 A1
(43) Pub. Date: Oct. 2, 2025

(54) DISPLAY DEVICE

(71) Applicant: Samsung Display Co., LTD., Yongin-si (KR)

(72) Inventors: Tak Young LEE, Yongin-si (KR); Hyuk KIM, Yongin-si (KR); Bo Gyeong KIM, Yongin-si (KR); Bo Yong CHUNG, Yongin-si (KR); Byung Seok CHOI, Yongin-si (KR)

(73) Assignee: Samsung Display Co., LTD., Yongin-si (KR)

(21) Appl. No.: 19/093,773

(22) Filed: Mar. 28, 2025

(30) Foreign Application Priority Data
Apr. 1, 2024 (KR) 10-2024-0044181

(51) Int. Cl. G09G 3/3225

(52) U.S. Cl. CPC G09G 3/3225; G09G 2300/043; G09G 2300/0819; G09G 2310/08

(57) ABSTRACT

A display device includes a light-emitting element, a first transistor connected between a driving voltage line and the light-emitting element, a capacitor connected between a gate electrode and a source electrode of the first transistor, and a second transistor connected between the capacitor and the source electrode of the first transistor. The capacitor and the seventh transistor are connected in series between the gate electrode of the first transistor and the source electrode of the first transistor.

### CROSS REFERENCE TO RELATED APPLICATION(S)

This application claims priority to and benefits of Korean Patent Application No. 10-2024-0044181 under 35 U.S.C. § 119, filed on Apr. 1, 2024, in the Korean Intellectual Property Office (KIPO), the entire contents of which are incorporated herein by reference.

### BACKGROUND

### 1. Technical Field

The disclosure relates to a display device with an extended range of data voltage.

### 2. Description of the Related Art

An organic light-emitting display apparatus includes display elements having luminance varying depending on electric current, for example, organic light-emitting diodes.

### SUMMARY

Aspects of the disclosure provide a display device with an extended range of data voltage.

According to an embodiment of the disclosure, a display device may include a light-emitting element, a first transistor connected between a driving voltage line and the light-emitting element, a capacitor connected between a gate electrode and a source electrode of the first transistor, and a second transistor connected between the capacitor and the source electrode of the first transistor. The capacitor and the second transistor may be connected in series between the gate electrode of the first transistor and the source electrode of the first transistor.

In an embodiment, the display device may further include a third transistor connected between a data line and the gate electrode of the first transistor.

In an embodiment, the display device may further include a fourth transistor connected between a reference voltage line and the gate electrode of the first transistor.

In an embodiment, the display device may further include a fifth transistor connected between an initialization voltage line and an anode electrode of the light-emitting element.

In an embodiment, the display device may further include a sixth transistor connected between the driving voltage line and a drain electrode of the first transistor.

In an embodiment, the display device may further include a seventh transistor connected between the source electrode of the first transistor and the anode electrode of the light-emitting element.

In an embodiment, the display device may further include a first gate line connected to a gate electrode of the third transistor, a second gate line connected to a gate electrode of the fourth transistor, a third gate line connected to a gate electrode of the fifth transistor, an emission line connected to a gate electrode of the sixth transistor, and a fourth gate line connected to a gate electrode of the seventh transistor and a gate electrode of the second transistor.

In an embodiment, the data line may transmit a data voltage, the first gate line may transmit a first gate signal, the second gate line may transmit a second gate signal, the third gate line may transmit a third gate signal, the fourth gate line may transmit a fourth gate signal, and the emission line may transmit an emission signal.

In an embodiment, in a first initialization period, each of the third gate signal and the fourth gate signal may have an active level, and each of the first gate signal, the second gate signal and the emission signal may have an inactive level.

In an embodiment, in a threshold voltage detection period after the first initialization period, each of the second gate signal and the emission signal may have the active level, and each of the first gate signal, the third gate signal and the fourth gate signal may have the inactive level.

In an embodiment, in a data write period after the threshold voltage detection period, the first gate signal may have the active level, each of the second gate signal, the third gate signal, the fourth gate signal and the emission signal may have the inactive level, and the data voltage may be applied to the data line.

In an embodiment, in a second initialization period after the data write period, each of the third gate signal and the fourth gate signal may have the active level, and each of the first gate signal, the second gate signal and the emission signal may have the inactive level.

In an embodiment, in an emission period after the second initialization period, each of the fourth gate signal and the emission signal may have the active level, and each of the first gate signal, the second gate signal and the third gate signal may have the inactive level.

In an embodiment, each of the first to seventh transistors may be an n-type transistor.

In an embodiment, a type of the second transistor and a type of at least one of the first transistor, the third transistor, the fourth transistor, the fifth transistor, the sixth transistor, and the seventh transistor may be different.

In an embodiment, the type of the second transistor and the type of the third transistor may be different.

In an embodiment, each of the first transistor, the third transistor, the fourth transistor, the fifth transistor, the sixth transistor, and the seventh transistor may be an n-type transistor, and the second transistor may be a p-type transistor.

In an embodiment, the display device may further include a first gate line connected to a gate electrode of the third transistor and the second transistor, a second gate line connected to a gate electrode of the fourth transistor, a third gate line connected to a gate electrode of the fifth transistor, an emission line connected to a gate electrode of the sixth transistor; and a fourth gate line connected to a gate electrode of the seventh transistor.

In an embodiment, the gate electrode of the second transistor and the gate electrode of the third transistor may be connected to the first gate line.

In an embodiment, each of the first to seventh transistors may include an oxide-based active layer.

A display device according to an embodiment of the disclosure may provide the following effects:

First, the range of data voltage may be extended. Accordingly, the display device according to an embodiment may express grayscales precisely.

Second, the voltage instability of the source electrode of a driving transistor may be improved.

Third, the pixel area may be utilized advantageously.

However, aspects of the disclosure are not restricted to the one set forth herein. The above and other aspects of the disclosure will become more apparent to one of ordinary skill in the art to which the disclosure pertains by referencing the detailed description of the disclosure given below.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view showing a display device according to an embodiment of the disclosure.

FIG. 2 is a schematic cross-sectional view showing a display device according to an embodiment of the disclosure.

FIG. 3 is a plan view showing a display unit of a display device according to an embodiment of the disclosure.

FIG. 4 is a schematic block diagram illustrating the display panel and the display driver according to an embodiment.

FIG. 5 is a schematic diagram of an equivalent circuit of a pixel of a display device according to an embodiment of the disclosure.

FIG. 6 is a schematic timing diagram of the first gate signal, the second gate signal, the third gate signal, the fourth gate signal, and the emission signal of FIG. 5.

FIG. 7 is a schematic diagram of an equivalent circuit of a pixel for illustrating an operation of the display device of FIG. 5 in the first initialization period of FIG. 6.

FIG. 8 is a schematic diagram of an equivalent circuit of a pixel for illustrating an operation of the display device of FIG. 5 in the threshold voltage detection period of FIG. 6.

FIG. 9 is a schematic diagram of an equivalent circuit of a pixel for illustrating an operation of the display device of FIG. 5 in the data write period of FIG. 6.

FIG. 10 is a schematic diagram of an equivalent circuit of a pixel for illustrating an operation of the display device of FIG. 5 in the second initialization period of FIG. 6.

FIG. 11 is a schematic diagram of an equivalent circuit of a pixel for illustrating an operation of the display device of FIG. 5 in the emission period of FIG. 6.

FIG. 12 is a schematic diagram of an equivalent circuit of a pixel of a display device according to an embodiment of the disclosure.

FIG. 13 is a schematic cross-sectional view showing a structure of a display element according to an embodiment of the disclosure.

FIGS. 14 to 17 are schematic cross-sectional views illustrating structures of light-emitting elements according to embodiments.

FIG. 18 is a schematic cross-sectional view showing an embodiment of the organic light-emitting diode of FIG. 16.

FIG. 19 is a schematic cross-sectional view showing an embodiment of the organic light-emitting diode of FIG. 17.

FIG. 20 is a schematic cross-sectional view illustrating a structure of a pixel of a display device according to an embodiment of the disclosure.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Features of various embodiments of the disclosure may be combined partially or totally. As will be clearly appreciated by those skilled in the art, technically various interactions and operations are possible. Various embodiments can be practiced individually or in combination.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

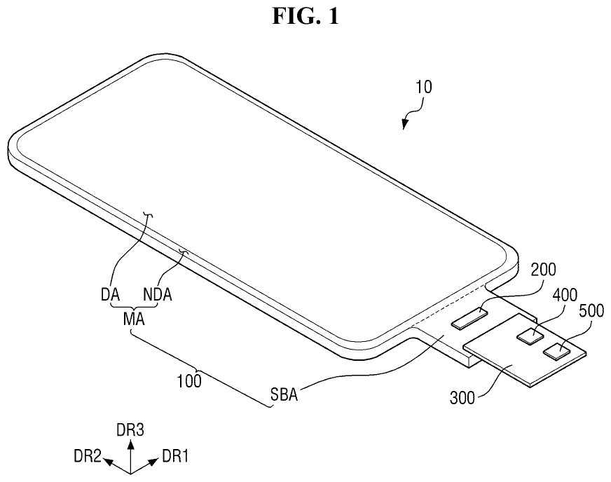

FIG. 1 is a perspective view showing a display device according to an embodiment of the disclosure.

Referring to FIG. 1, a display device 10 may be employed by portable electronic devices such as a mobile phone, a smart phone, a tablet PC, a mobile communications terminal, an electronic notebook, an electronic book, a portable multimedia player (PMP), a navigation device and an ultra mobile PC (UMPC). For example, the display device 10 may be used as a display unit of a television, a laptop computer, a monitor, an electronic billboard, or the Internet of Things (IOT). For example, the display device 10 may be applied to wearable devices such as a smart watch, a watch phone, a glasses-type display, and a head-mounted display (HMD) device.

The display device 10 may have a shape similar to a quadrangular shape in a plan view. For example, the display device 10 may have a shape similar to a rectangle having shorter sides in a first direction DR1 and longer sides in a second direction DR2. The corners where the shorter sides in the first direction DR1 meet the longer sides in the second direction DR2 may be rounded with a curvature or may be a right angle. The shape of the display device 10 in a plan view is not limited to a quadrangular shape, but may be formed in a shape similar to other polygonal shapes, a circular shape, or an elliptical shape.

The display device 10 may include a display panel 100, a display driver 200, a circuit board 300, a touch driver 400, and a power supply unit 500.

The display panel 100 may include a main area MA and a subsidiary area SBA.

The main area MA may include a display area DA having pixels for displaying images, and a non-display area NDA located adjacent to the display area DA. The display area DA may output lights from multiple emission areas or multiple open areas. For example, the display panel 100 may include a pixel circuit including switching elements, a pixel-defining layer that defines the emission areas or the open areas, and self-light-emitting elements.

For example, the self-light-emitting element ED may include, but is not limited to, at least one of an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The non-display area NDA may be located on a side of the display area DA. The non-display area NDA may be defined as the edge of the main area MA of the display panel 100. The non-display area NDA may include a gate driver (not shown) that applies gate signals to gate lines, and fan-out lines (not shown) that connect the display driver 200 with the display area DA.

The subsidiary area SBA may be extended from a side of the main area MA. The subsidiary area SUB may include a flexible material that can be bent, folded, or rolled. For example, in case that the subsidiary area SBA is bent, the subsidiary area SBA may overlap the main area MA in a thickness direction (e.g., third direction DR3). The subsidiary area SBA may include pads connected to the display driver 200 and the circuit board 300. In another embodiment, the subsidiary area SBA may be omitted, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap the main area MA in the thickness direction (third direction DR3) as the subsidiary area SBA is bent. In another embodiment, the display driver 200 may be mounted on the circuit board 300.

The circuit board 300 may be attached on the pad area of the display panel 100 using an anisotropic conductive film (ACF). Lead lines of the circuit board 300 may be electrically connected to the pads of the display panel 300. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be electrically connected to a touch sensing unit of the display panel 100. The touch driver 400 may supply a touch driving signal to multiple touch electrodes of the touch sensing unit and may sense a change in the capacitance between the touch electrodes. For example, the touch driving signals may be pulse signals having a frequency. The touch driver 400 may determine whether there is an input and may find the coordinates of the input based on the amount of the change in the capacitance between the touch electrodes. The touch driver 400 may be implemented as an integrated circuit (IC).

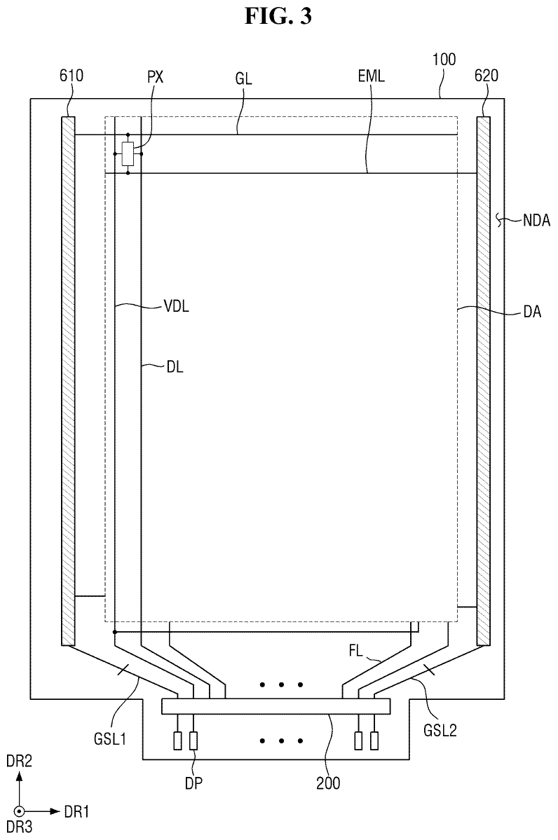

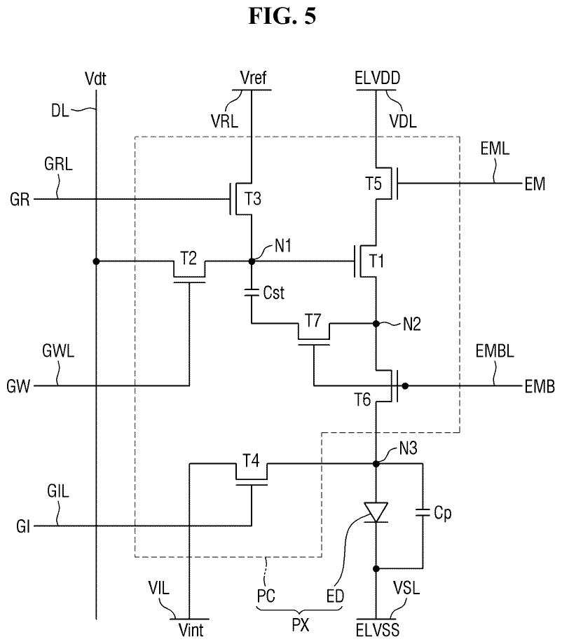

The power supply unit 500 may be disposed on the circuit board 300 and apply a supply voltage to the display drivers 200 and the display panel 100. The power supply unit 500 may generate a driving voltage to supply to a driving voltage line VDL (FIG. 3), may generate an initialization voltage to supply to an initialization voltage line VIL (FIG. 5), may generate a reference voltage to supply to a reference voltage line VRL (FIG. 5), and may generate a common voltage to supply to a common voltage line. The common voltage of the common voltage line may be supplied to the common electrode common to the light-emitting elements ED of multiple pixels. The driving voltage may be a high-level voltage for driving the light-emitting elements ED, and the common voltage may be a low-level voltage for driving the light-emitting elements ED.

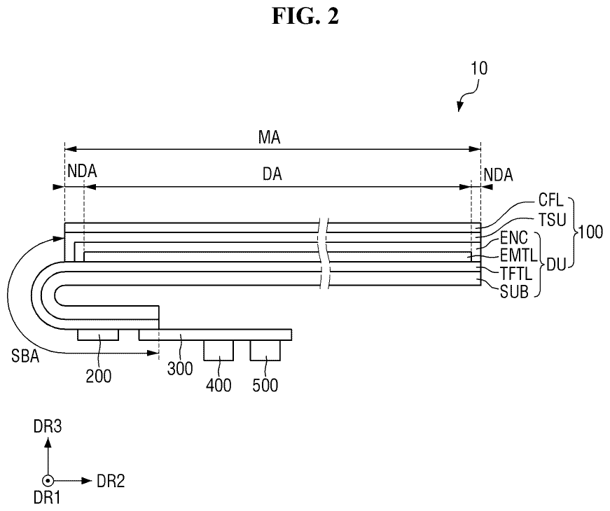

FIG. 2 is a schematic cross-sectional view showing a display device according to an embodiment of the disclosure.

Referring to FIG. 2, the display panel 100 may include a display unit DU, a touch sensing unit TSU, and a color filter layer CFL. The display unit DU may include a substrate SUB, a thin-film transistor layer TFTL, an emission layer EMTL and an encapsulation layer ENC.

The substrate SUB may be a base substrate or a base member. The substrate SUB may be a flexible substrate that can be bent, folded, or rolled. For example, the substrate SUB may include, but is not limited to, a polymer resin including polyimide PI. In another embodiment, the substrate SUB may include a glass material or a metal material.

The thin-film transistor layer TFTL may be disposed on the substrate SUB. The thin-film transistor layer TFTL may include multiple thin-film transistors forming pixel circuits of pixels. The thin-film transistor layer TFTL may include gate lines, data lines, voltage lines, gate control lines, fan-out lines for connecting the display driver 200 with the data lines, lead lines for connecting the display driver 200 with the pads, etc. Each of the thin-film transistors may include a semiconductor region, a source electrode, a drain electrode, and a gate electrode. For example, in case that the gate driver is formed on a side of the non-display area NDA of the display panel 100, the gate driver may include thin-film transistors.

The thin-film transistor layer TFTL may be disposed in the display area DA, the non-display area NDA and the subsidiary area SBA. The thin-film transistors in each of the pixels, the gate lines, the data lines and the voltage lines in the thin-film transistor layer TFTL may be disposed in the display area DA. The gate control lines and the fan-out lines in the thin-film transistor layer TFTL may be disposed in the non-display area NDA. The lead lines of the thin-film transistor layer TFTL may be disposed in the subsidiary area SBA.

The emission layer EMTL may be disposed on the thin-film transistor layer TFTL. The emission layer EMTL may include multiple light-emitting elements ED (FIG. 5) in each of which a pixel electrode, an emissive layer and a common electrode are stacked on one another sequentially to emit light, and a pixel-defining film for defining the pixels. The light-emitting elements ED in the emission layer EMTL may be disposed in the display area DA.

For example, the emission layer EMTL may be an organic light-emitting layer including an organic material. The emission layer EMTL may include a hole transporting layer, an organic light-emitting layer and an electron transporting layer. In case that the pixel electrode receives a voltage and the common electrode receives a cathode voltage through the thin-film transistors in the thin-film transistor layer TFTL, the holes and electrons may move to the organic light-emitting layer through the hole transporting layer and the electron transporting layer, respectively, and combine in the organic light-emitting layer to emit light. For example, the pixel electrode may be an anode electrode and the common electrode may be a cathode electrode. It is, however, to be understood that the disclosure is not limited thereto.

In another embodiment, the light-emitting elements ED may include quantum-dot light-emitting diodes each including a quantum-dot emissive layer, inorganic light-emitting diodes each including an inorganic semiconductor, or micro light-emitting diodes.

The encapsulation layer ENC may cover the upper and side surfaces of the emission layer EMTL, and may protect the emission layer EMTL. The encapsulation layer ENC may include at least one inorganic film and at least one organic film for encapsulating the emission layer EMTL.

The touch sensing unit TSU may be disposed on the encapsulation layer ENC. The touch sensing unit TSU may include multiple touch electrodes for sensing a user's touch by capacitive sensing, and touch lines connecting the touch electrodes with the touch driver 400. For example, the touch sensing unit TSU may sense a user's touch by mutual capacitance sensing or self-capacitance sensing.

In another embodiment, the touch sensing unit TSU may be disposed on a separate substrate disposed on the display unit DU, and the substrate supporting the touch sensing unit TSU may be a base member encapsulating the display unit DU.

The touch electrodes of the touch sensing unit TSU may be disposed in a touch sensor area in the display area DA. The touch lines of the touch sensing unit TSU may be disposed in a touch peripheral area in the non-display area NDA.

The color filter layer CFL may be disposed on the touch sensing unit TSU. The color filter layer CFL may include multiple color filters corresponding to the emission areas, respectively. Each of the color filters may selectively transmit light of a wavelength and block or absorb lights of other wavelengths. The color filter layer CFL may absorb some of lights introduced from the outside of the display device 10 to reduce the reflection of external light. Accordingly, the color filter layer CFL may prevent distortion of colors due to the reflection of external light.

Since the color filter layer CFL is disposed directly on the touch sensing unit TSU, the display device 10 may require no separate substrate for the color filter layer CFL. Therefore, the thickness of the display device 10 may be relatively reduced.

The subsidiary area SBA of the display panel 100 may be extended from a side of the main area MA. The subsidiary area SUB may include a flexible material that can be bent, folded, or rolled. For example, in case that the subsidiary area SBA is bent, the subsidiary area SBA may overlap the main area MA in the thickness direction (third direction DR3). The subsidiary area SBA may include pads electrically connected to the display driver 200 and the circuit board 300.

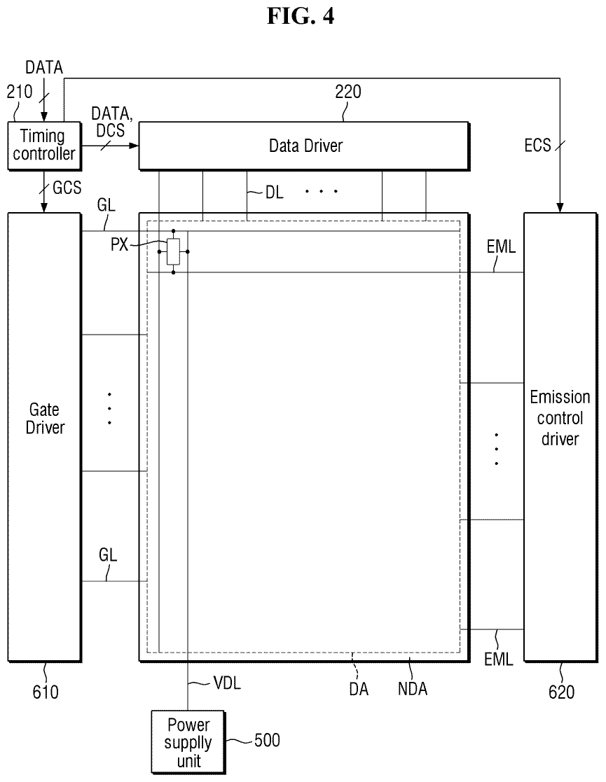

FIG. 3 is a plan view showing the display unit of the display device according to an embodiment of the disclosure. FIG. 4 is a schematic block diagram illustrating the display panel and the display driver according to an embodiment.

Referring to FIGS. 3 and 4, the display panel 100 may include the display area DA and the non-display area NDA.

The display area DA may include multiple pixels PX, multiple driving voltage lines VDL connected to the pixels PX, multiple gate lines GL of multiple common voltage lines VSL (see FIG. 5), multiple emission lines EML, and multiple data lines DL.

Each of the pixels PX may be connected to a gate line GL, a data line DL, an emission line EML, a driving voltage line VDL, and a common voltage line VSL. Each of the pixels PX may include at least one transistor, a light-emitting element ED, and a capacitor.

The gate lines GL may be extended in the first direction DR1 and may be spaced apart from one another in the second direction DR2 intersecting the first direction DR1. The gate lines GL may be arranged in the second direction DR2. The gate lines GL may sequentially supply gate signals to the pixels PX.

The emission lines EML may be extended in the first direction DR1 and may be spaced apart from one another in the second direction DR2. The emission lines EML may be arranged in the second direction DR2. The emission lines EML may sequentially supply emission signals to the pixels PX.

The data lines DL may be extended in the second direction DR2 and may be spaced apart from one another in the first direction DR1. The data lines DL may be arranged along the first direction DR1. The data lines DL may supply data voltages to the pixels PX. The data voltage may determine the luminance of each of the pixels PX.

The driving voltage lines VDL may be extended in the second direction DR2 and may be spaced apart from one another in the first direction DR1. The driving voltage lines VDL may be arranged in the first direction DR1. The driving voltage lines VDL may supply a first driving voltage to the pixels PX. The first driving voltage may be a high-level voltage for driving light-emitting elements ED of the pixels PX.

The non-display area NDA may surround the display area DA. The non-display area NDA may include a gate driver 610, an emission control driver 620, fan-out lines FL, a first gate control line GSL1 and a second gate control line GSL2.

The fan-out lines FL may be extended from the display driver 200 to the display area DA. The fan-out lines FL may supply the data voltage received from the display driver 200 to the data lines DL.

The first gate control line GSL1 may be extended from the display driver 200 to the gate driver 610. The first gate control line GSL1 may supply a gate control signal GCS received from the display driver 200 to the gate driver 610.

The second gate control line GSL2 may be extended from the display driver 200 to the emission control driver 620. The second gate control line GSL2 may supply an emission control signal ECS received from the display driver 200 to the emission control driver 620.

The subsidiary area SBA may be extended from a side of the non-display area NDA.

The subsidiary area SBA may include the display driver 200 and pads DP. The pads DP may be disposed closer to an edge of the subsidiary area SBA than the display driver 200. The pads DP may be electrically connected to the circuit board 300 through an anisotropic conductive film (ACF).

The display driver 200 may include a timing controller 210 and a data driver 220.

The timing controller 210 may receive digital video data DATA and timing signals from the circuit board 300. The timing controller 210 may generate a data control signal DCS to control the operation timing of the data driver 220, may generate a gate control signal GCS to control the operation timing of the gate driver 610, and may generate an emission control signal ECS to control the operation timing of the emission control driver 620 based on the timing signals. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and may supply them to the data lines DL through the fan-out lines FL. The gate signals from the gate driver 610 may be used to select pixels PX to which a data voltage is applied, and the selected pixels PX may receive the data voltage through the data lines DL.

The power supply unit 500 may be disposed on the circuit board 300 to prevent a supply voltage to the display drivers 200 and the display panel 100. The power supply unit 500 may generate a driving voltage to supply to the driving voltage line VDL, may generate an initialization voltage to supply to the initialization voltage line VIL, and may generate a common voltage to supply to a common electrode shared by the light-emitting elements ED of multiple pixels.

The gate driver 610 may be disposed on an outer side of the display area DA or on an outer side of the non-display area NDA, and the emission control driver 620 may be disposed on an opposite outer side of the display area DA or on an opposite outer side of the non-display area NDA. It should be understood, however, that the disclosure is not limited thereto. In another embodiment, the gate driver 610 and the emission control driver 620 may be disposed on a side or an opposite side of the non-display area NDA.

The gate driver 610 may include multiple thin-film transistors for generating gate signals based on the gate control signal GCS. The emission control driver 620 may include multiple transistors for generating emission signals based on the emission control signal ECS. For example, the transistors of the gate driver 610, the transistors of the emission control driver 620, and the transistors of each of the pixels PX may be formed on a same layer. The gate driver 610 may provide gate signals to the gate lines GL, and the emission control driver 620 may provide emission signals to the emission lines EML.

FIG. 5 is a schematic diagram of an equivalent circuit of a pixel of a display device according to an embodiment of the disclosure.

Referring to FIG. 5, a pixel PX may be connected to a first gate line GWL, a second gate line GRL, a third gate line GIL, a fourth gate line EMBL, an emission line EML, a data line DL, a driving voltage line VDL, a common voltage line VSL, a reference voltage line VRL, and an initialization voltage line VIL.

A pixel (e.g., the pixel PX1) may include a pixel circuit PC and a light-emitting element ED. The pixel circuit PC may include a first transistor T1, a second transistor T2, a third transistor T3, a fourth transistor T4, a fifth transistor T5, a sixth transistor T6, a seventh transistor T7 and a capacitor Cst.

The first transistor T1 may include a gate electrode, a source electrode, and a drain electrode. The first transistor T1 may control a source-drain current (hereinafter referred to as a driving current) according to a data voltage applied to the gate electrode. The driving current flowing through the channel region of the first transistor T1 may be proportional to a square of the difference between the threshold voltage and the voltage (e.g., gate-source voltage) between the source electrode and the gate electrode of the first transistor T1 (Isd=k×(Vsg−Vth)²), where Isd may be a driving current, k may be a proportional coefficient determined by the structure and physical properties of the first transistor T1, Vsg may be a source-gate voltage of the first transistor T1, and Vth may be a threshold voltage of the first transistor T1. The drain electrode of the first transistor T1 may be connected to the driving voltage line VDL that transmits a driving voltage ELVDD (e.g., a high-level voltage).

The light-emitting element ED may receive the driving current to emit light. The amount or the brightness of the light emitted from the light-emitting element ED may be proportional to the magnitude of the driving current. The light-emitting element ED may be an organic light-emitting diode including a first electrode, a second electrode, and an organic light-emitting layer disposed between the first electrode and the second electrode. In another embodiment, the light-emitting element ED may be an inorganic light-emitting element ED including a first electrode, a second electrode, and an inorganic semiconductor disposed between the first electrode and the second electrode. In another embodiment, the light-emitting element ED may be a quantum-dot light-emitting element including a first electrode, a second electrode, and a quantum-dot emissive layer between the first electrode and the second electrode. In another embodiment, the light-emitting element ED may be a micro light-emitting diode. The first electrode of the light-emitting element ED may be electrically connected to a third node N3, and the second electrode of the light-emitting element ED may be connected to the common voltage line VSL. The second electrode of the light-emitting element ED may receive a common voltage ELVSS (e.g., a low-level voltage) from the common voltage line VSL. A capacitor Cp connected between the first electrode and the second electrode of the light-emitting element ED may be a parasitic capacitor of the light-emitting element ED.

The second transistor T2 may be controlled by a first gate signal GW, and the second transistor T2 may be connected between the data line DL and a first node N1. The second transistor T2 may be turned on by a first gate signal GW of the first gate line GWL to electrically connect the data line DL with the first node N1, that is the gate electrode of the first transistor T1. The gate electrode of the second transistor T2 may be electrically connected to the first gate line GWL, the drain electrode of the second transistor T2 may be electrically connected to the data line DL, and the source electrode thereof may be electrically connected to the first node N1.

The third transistor T3 may be controlled by a second gate signal GR, and the third transistor T3 may be connected between the reference voltage line VRL and the first node N1. The third transistor T3 may be turned on in response to the second gate signal GR of the second gate line GRL to electrically connect the first node NI with the reference voltage line VRL. A gate electrode of the third transistor T3 may be electrically connected to the second gate line GRL, the drain electrode may be electrically connected to the first node N1, and the source electrode may be electrically connected to the reference voltage line VRL. The reference voltage line VRL may transmit a reference voltage Vref.

The fourth transistor T4 may be controlled by a third gate signal GI, and the fourth transistor T4 may be connected between the third node N3 and the initialization voltage line VIL. The fourth transistor T4 may be turned on by a third gate signal GI of the third gate line GIL to electrically connect the second node N3 with the initialization voltage line VIL. The gate electrode of the fourth transistor T4 may be electrically connected to the third gate line GIL, the drain electrode thereof may be electrically connected to the third node N3, and the source electrode thereof may be electrically connected to the initialization voltage line VIL. The initialization voltage line VIL may transmit an initializing voltage Vint. According to an embodiment, the initializing voltage Vint may be smaller than the reference voltage Vref. The initializing voltage Vint may be smaller than the common voltage ELVSS.

The fifth transistor T5 may be controlled by the emission signal EM, and the fifth transistor T5 may be connected between the driving voltage line VDL and the drain electrode of the first transistor T1. The fifth transistor T5 may be turned on by the emission signal EM of the emission line EML to electrically connect the driving voltage line VDL with the drain electrode of the first transistor T1. The gate electrode of the fifth transistor T5 may be electrically connected to the emission line EML, the drain electrode of the fifth transistor T5 may be electrically connected to the driving voltage line VDL, and the source electrode of the fifth transistor T5 may be electrically connected to the drain electrode of the first transistor T1. The driving voltage line VDL may transmit the driving voltage ELVDD. According to an embodiment, the driving voltage ELVDD may be greater than the common voltage ELVSS.

The sixth transistor T6 may be controlled by a fourth gate signal EMB, and the sixth transistor T6 may be connected between the second node N2 and the third node N3. The sixth transistor T6 may be turned on by the fourth gate signal EMB of the fourth gate line EMBL to electrically connect the second node N2 with the third node N3. The gate electrode of the sixth transistor T6 may be electrically connected to the fourth gate line EMBL, the drain electrode of the sixth transistor T6 may be electrically connected to the second node N2, and the source electrode of the sixth transistor T6 may be electrically connected to the third node N3.

The seventh transistor T7 may be controlled by the fourth gate signal EMBL, and the seventh transistor T7 may be connected between the second electrode of the capacitor Cst and the second node N2. The seventh transistor T7 may be turned on by the fourth gate signal EMB of the fourth gate line EMBL to electrically connect the second electrode of the capacitor Cst with the second node N2. The gate electrode of the seventh transistor T7 may be electrically connected to the fourth gate line EMBL, the drain electrode of the seventh transistor T7 may be electrically connected to the second electrode of the capacitor Cst, and the source electrode of the seventh transistor T7 may be electrically connected to the second node N2.

The capacitor Cst may be electrically connected between the first node N1 and the drain electrode of the seventh transistor T7. For example, the first electrode of the capacitor Cst may be electrically connected to the first node N1, and the second electrode of the capacitor Cst may be electrically connected to the drain electrode of the seventh transistor T7. In case that the seventh transistor T7 is turned on, the capacitor Cst may hold the potential difference across the first node N1 and the second node N2.

At least one of the first transistor T1, the second transistor T2, the third transistor T3, the fourth transistor T4, the fifth transistor T5, the sixth transistor T6 and the seventh transistor T7 may be an n-type transistor including an oxide-based active layer. For example, the first to seventh transistors may each be an n-type transistor including an oxide-based active layer. For example, each of the first to seventh transistors may be an n-type transistor including an oxide-based active layer. A transistor including an oxide-based active layer may have a coplanar structure in which a gate electrode is disposed at the top. A transistor including an oxide-based active layer may output current introduced into the drain electrode via the source electrode based on a gate-high voltage applied to the gate electrode.

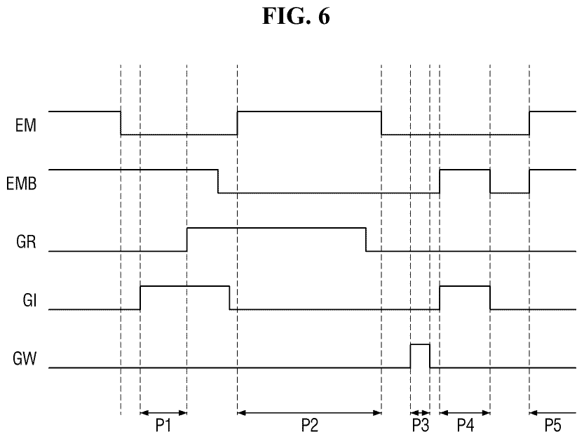

FIG. 6 is a schematic timing diagram of the first gate signal GW, the second gate signal GR, the third gate signal GI, the fourth gate signal EMB, and the emission signal EM of FIG. 5.

Referring to FIG. 6, the display device 10 may operate based on a first initialization period P1, a threshold voltage detection period P2, a data write period P3, a second initialization period P4, and an emission period P5.

The first gate signal GW, the second gate signal GR, the third gate signal GI, the fourth gate signal EMB and the emission signal EM may have an active level or an inactive level for each of the periods P1, P2, P3, P4 and P5. The active level of each of the signals GW, GR, GI, EMB and EM may be a voltage at the level that can turn on the respective transistors to which the signals are applied. In other words, the signals at the active level may have a value greater than the threshold voltages of the respective transistors. For example, in case that a transistor is an n-type transistor, the active level of the signal applied to the gate electrode of the transistor may be a high level (e.g., a positive polarity level or a high voltage level).

The inactive level of each of the signals GW, GR, GI, EM and EMB may be a voltage at the level that can turn off the respective transistors. In other words, the signals at the inactive level may have a value smaller than the threshold voltages of the respective transistors. For example, in case that a transistor is an n-type transistor, the inactive level of the signal applied to the gate electrode of the transistor may be a low level (e.g., a negative polarity level or a low voltage level).

For example, in case that a transistor is a p-type transistor, an active level of a signal applied to the gate electrode of the transistor may be a low level (e.g., a negative polarity level or low voltage level), and an inactive level of a signal applied to the gate electrode of the transistor may be a high level (e.g., a positive polarity level or a high voltage level).

In the first initialization period P1, the third gate signal GI and the fourth gate signal EMB may each have an active level. On the other hand, in the first initialization period P1, the first gate signal GW, the second gate signal GR, and the emission signal EM may each have an inactive level.

In the threshold voltage detection period P2, the second gate signal GR and the emission signal EM may each have the active level. On the other hand, in the threshold voltage detection period P2, the first gate signal GW, the third gate signal GI, and the fourth gate signal EMB may each have the inactive level.

In the data write period P3, the first gate signal GW may have the active level. On the other hand, in the data write period P3, the second gate signal GR, the third gate signal GI, the fourth gate signal EMB, and the emission signal EM may each have the inactive level. In the data write period P3, a data voltage Vdt may be applied to the data line DL.

In the second initialization period P4, the third gate signal GI and the fourth gate signal EMB may each have the active level. On the other hand, in the second initialization period P4, the first gate signal GW, the second gate signal GR, and the emission signal EM may each have an inactive level.

In the emission period P5, the fourth gate signal EMB and the emission signal EM may each have the active level. On the other hand, in the emission period P5, the first gate signal GW, the second gate signal GR, and the third gate signal GI may each have the inactive level.

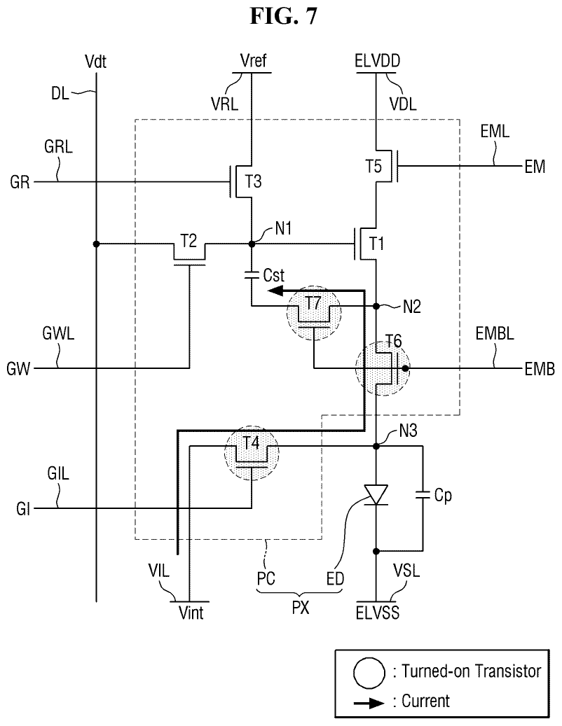

Operations of the display device 10 according to an embodiment of the disclosure will be described with reference to FIGS. 7 to 11. It should be noted that in FIGS. 7 to 11, the transistors surrounded by the dashed circles are turned on while the transistors other than the transistors surrounded by the dashed circles are turned off.

Initially, with reference to FIGS. 6 and 7, the operation of the display device 10 in the first initialization period P1 will be described below.

FIG. 7 is a schematic diagram of an equivalent circuit of a pixel for illustrating the operation of the display device 10 of FIG. 5 in the first initialization period P1 of FIG. 6.

As shown in FIG. 6, in the first initialization period P1, the third gate signal GI and the fourth gate signal EMB may each have the active level. On the other hand, in the first initialization period P1, the first gate signal GW, the second gate signal GR, and the emission signal EM may each have an inactive level.

The third gate signal GI at the active level may be applied to the gate electrode of the fourth transistor T4 through the third gate line GIL. Accordingly, the fourth transistor T4 may be turned on.

The fourth gate signal EMB at the active level may be applied to the gate electrode of the sixth transistor T6 and the gate electrode of the seventh transistor T7 through the fourth gate line EMBL. Accordingly, each of the sixth transistor T6 and the seventh transistor T7 may be turned on.

The first gate signal GW at the inactive level may be applied to the gate electrode of the second transistor T2 through the first gate line GWL. Accordingly, the second transistor T2 may be turned off.

The second gate signal GR at the inactive level may be applied to the gate electrode of the third transistor T3 through the second gate line GRL. Accordingly, the third transistor T3 may be turned off.

The emission signal EM at the inactive level may be applied to the gate electrode of the fifth transistor T5 through the emission line EML. Accordingly, the fifth transistor T5 may be turned off.

As the fourth transistor T4, the sixth transistor T6 and the seventh transistor T7 are turned on, the initializing voltage Vint may be applied to the second node N2, the third node N3 and the second electrode of the capacitor through the fourth transistor T4, the sixth transistor T6 and the seventh transistor T7. Accordingly, the source electrode of the first transistor T1 connected to the second node N2 and the first electrode of the light-emitting element ED connected to the third node N3 may each be initialized to the initializing voltage Vint.

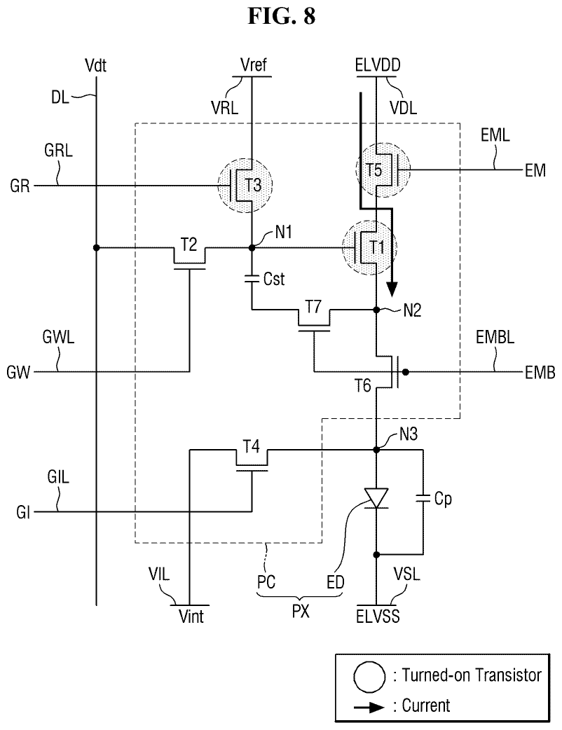

Subsequently, with reference to FIGS. 6 and 8, the operation of the display device 10 in the threshold voltage detection period P2 will be described below.

FIG. 8 is a schematic diagram of an equivalent circuit of a pixel for illustrating the operation of the display device 10 of FIG. 5 in the threshold voltage detection period P2 of FIG. 6.

As shown in FIG. 6, in the threshold voltage detection period P2, the second gate signal GR and the emission signal EM may each have the active level. On the other hand, in the threshold voltage detection period P2, the first gate signal GW, the third gate signal GI, and the fourth gate signal EMB may each have the inactive level.

The second gate signal GR at the active level may be applied to the gate electrode of the third transistor T3 through the second gate line GRL. Accordingly, the third transistor T3 may be turned on.

The emission signal EM at the active level may be applied to the gate electrode of the fifth transistor T5 through the emission line EML. Accordingly, the fifth transistor T5 may be turned on.

The first gate signal GW at the inactive level may be applied to the gate electrode of the second transistor T2 through the first gate line GWL. Accordingly, the second transistor T2 may be turned off.

The third gate signal GI at the inactive level may be applied to the gate electrode of the fourth transistor T4 through the third gate line GIL. Accordingly, the fourth transistor T4 may be turned off.

The fourth gate signal EMB at the inactive level may be applied to the gate electrode of the sixth transistor T6 and the gate electrode of the seventh transistor T7 through the fourth gate line EMBL. Accordingly, each of the sixth transistor T6 and the seventh transistor T7 may be turned off.

The reference voltage Vref may be applied to the first node NI through the turned-on third transistor T3, and accordingly, the voltage of the gate electrode of the first transistor T1 (e.g., the first node N1) may be held at the reference voltage Vref. The voltage of the source electrode of the first transistor T1 (e.g., second node N2) may be the initializing voltage Vint applied in the previous period (e.g., the first initialization period P1). Since the initializing voltage Vint is smaller than the difference voltage (Vref−Vth) between the reference voltage Vref and the threshold voltage (e.g., voltage Vth) of the first transistor T1, the first transistor T1 may be turned on. In other words, since the gate-source voltage (Vref−Vint) of the first transistor T1 is greater than the threshold voltage Vth of the first transistor T1, the first transistor T1 may be turned on.

On the other hand, in the threshold voltage detection period P2, the second node N2 may remain floating as the fourth transistor T4, the sixth transistor T6 and the seventh transistor T7 are turned off. Accordingly, the voltage of the second node N2 may gradually increase by the current flowing through the turned-on first transistor T1. In other words, as each of the fourth transistor T4, the sixth transistor T6 and the seventh transistor T7 is turned off, the initialization voltage Vint applied to the second node N2 may be interrupted. Accordingly, the voltage of the second node N2 may increase by the driving voltage ELVDD supplied through the turned-on first transistor T1. As a result, the current flowing through the first transistor T1 may gradually decrease. Accordingly, the gate-source voltage of the first transistor T1 may gradually decrease, and the first transistor T1 may be turned off at the moment the gate-source voltage reaches the threshold voltage Vth of the first transistor T1. The threshold voltage of the first transistor T1 may be detected using a source follower configuration. The detected threshold voltage Vth of the first transistor T1 may be reflected in the second node N2. In the threshold voltage detection period P2, the voltage of the first node N1 may have the level of the reference voltage Vref, and the voltage of the second node N2 may have the level equal to the difference voltage (Vref−Vth) between the threshold voltage Vth of the first transistor T1 and the reference voltage Vref.

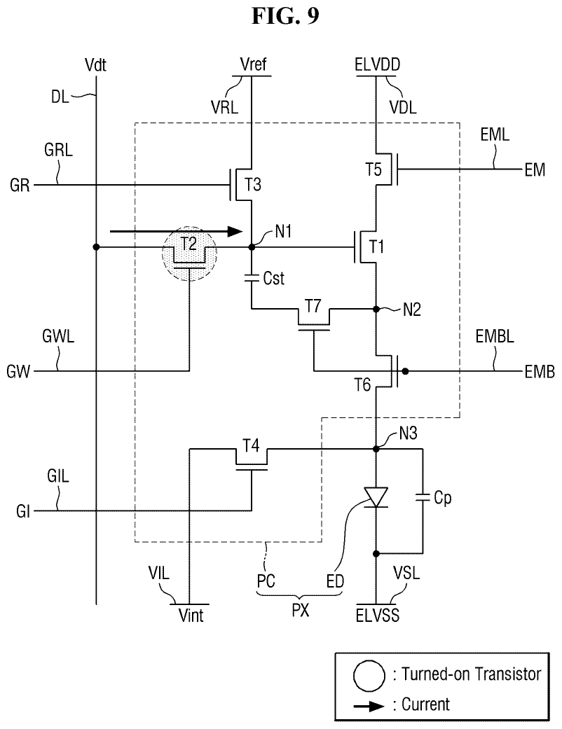

Subsequently, with reference to FIGS. 6 and 9, the operation of the display device 10 in the data write period P3 will be described below.

FIG. 9 is a schematic diagram of an equivalent circuit of a pixel for illustrating the operation of the display device 10 of FIG. 5 in the data write period P3 of FIG. 6.

As shown in FIG. 6, in the data write period P3, the first gate signal GW may have the active level. On the other hand, in the data write period P3, the second gate signal GR, the third gate signal GI, the fourth gate signal EMB, and the emission signal EM may each have the inactive level. In this data write period P3, a data voltage Vdt may be applied to the data line DL.

The first gate signal GW at the active level may be applied to the gate electrode of the second transistor T2 through the first gate line GWL. Accordingly, the second transistor T2 may be turned on.

The second gate signal GR at the inactive level may be applied to the gate electrode of the third transistor T3 through the second gate line GRL. Accordingly, the third transistor T3 may be turned off.

The third gate signal GI at the inactive level may be applied to the gate electrode of the fourth transistor T4 through the third gate line GIL. Accordingly, the fourth transistor T4 may be turned off.

The fourth gate signal EMB at the inactive level may be applied to the gate electrode of the sixth transistor T6 and the gate electrode of the seventh transistor T7 through the fourth gate line EMBL. Accordingly, each of the sixth transistor T6 and the seventh transistor T7 may be turned off.

The emission signal EM at the inactive level may be applied to the gate electrode of the first transistor T5 through the emission line EML.

As the second transistor T2 is turned on, the data voltage Vdt from the data line DL may be applied to the first node N1 through the turned-on second transistor T2. In other words, the data voltage Vdt from the data line DL may be applied to the gate electrode of the first transistor T1. Accordingly, the voltage of the first node N1 may be converted from the reference voltage Vref to the data voltage Vdt.

On the other hand, in the data write period P3, as each of the first transistor T1, the sixth transistor T6 and the seventh transistor T7 is turned off, the second node N2 may remain floating. As described above, since the electrical connection between the capacitor Cst and the second node N2 is substantially blocked by the turned-off seventh transistor T7, the voltage of the second node N2 may be held as it is even if the voltage of the first node N1 changes due to the application of the data voltage Vdt. For example, in the data write period P3, regardless of a change in voltage of the first node N1, the voltage of the second node N2 may be held at the level of the difference voltage (Vref−Vth) between the reference voltage Vref and the threshold voltage Vth of the first transistor T1 as described above.

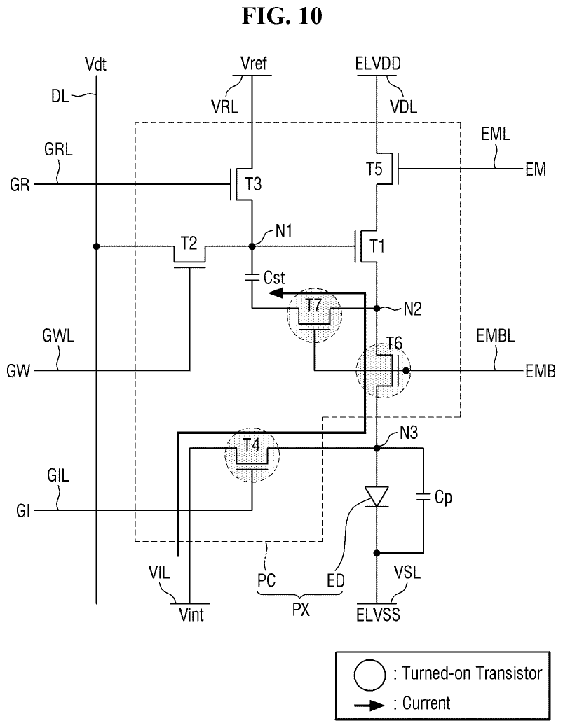

Subsequently, with reference to FIGS. 6 and 10, the operation of the display device 10 in the second initialization period P4 will be described below.

FIG. 10 is a schematic diagram of an equivalent circuit of a pixel for illustrating the operation of the display device 10 of FIG. 5 in the second initialization period P4 of FIG. 6.

As shown in FIG. 6, in the second initialization period P4, the third gate signal GI and the fourth gate signal EMB may each have the active level. On the other hand, in the second initialization period P4, the first gate signal GW, the second gate signal GR, and the emission signal EM may each have an inactive level.

The third gate signal GI at the active level may be applied to the gate electrode of the fourth transistor T4 through the third gate line GIL. Accordingly, the fourth transistor T4 may be turned on.

The fourth gate signal EMB at the active level may be applied to the gate electrode of the sixth transistor T6 and the gate electrode of the seventh transistor T7 through the fourth gate line EMBL. Accordingly, each of the sixth transistor T6 and the seventh transistor T7 may be turned on.

The first gate signal GW at the inactive level may be applied to the gate electrode of the second transistor T2 through the first gate line GWL. Accordingly, the second transistor T2 may be turned off.

The second gate signal GR at the inactive level may be applied to the gate electrode of the third transistor T3 through the second gate line GRL. Accordingly, the third transistor T3 may be turned off.

The emission signal EM at the inactive level may be applied to the gate electrode of the fifth transistor T5 through the emission line EML. Accordingly, the fifth transistor T5 may be turned off.

As the fourth transistor T4, the sixth transistor T6 and the seventh transistor T7 are turned on, the initializing voltage Vint may be applied to the second node N2, the third node N3 and the second electrode of the capacitor Cst through the fourth transistor T4, the sixth transistor T6 and the seventh transistor T7. Accordingly, the source electrode of the first transistor T1 connected to the second node N2 and the first electrode of the light-emitting element ED connected to the third node N3 may each be initialized to the initializing voltage Vint.

On the other hand, in the second initialization period P4, each of the second transistor T2 and the third transistor T3 may be turned off, and thus the first node NI may remain floating. As described above, since the capacitor Cst and the second node N2 are electrically connected with each other by the turned-on seventh transistor T7, the amount of voltage change in the second node N2 may be reflected in the first node N1. For example, as described above, as the second node N2 is converted to the initialization voltage Vint, the threshold voltage Vth of the first transistor T1 may be reflected to the first node N1 by coupling of the capacitor Cst. For example, in the second initialization period P4, the voltage of the second node N2 may have the level of the initializing voltage Vint, and the voltage of the first node N1 may have the level of Vdt−((Vref−Vth)−Vint). The voltage Vdt−((Vref−Vth)−Vint) of the first node NI where the threshold voltage Vth is reflected may be stored and held by the capacitor Cst.

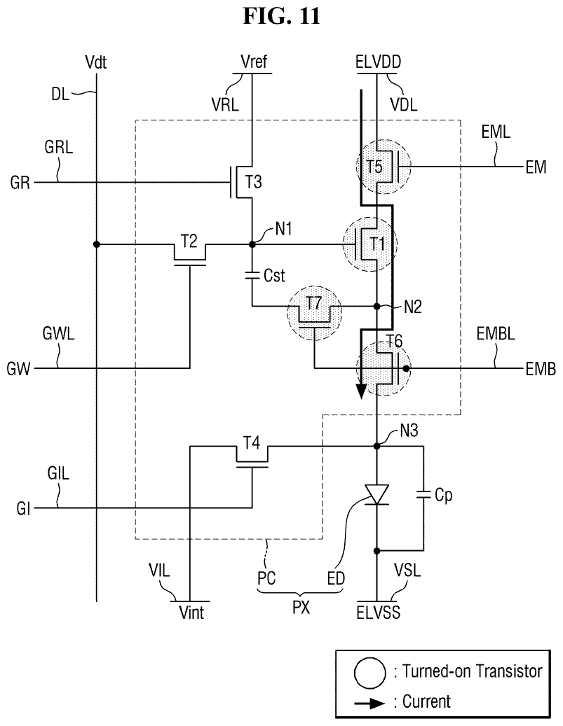

Subsequently, with reference to FIGS. 6 and 11, the operation of the display device 10 in the emission period P5 will be described below.

FIG. 11 is a schematic diagram of an equivalent circuit of a pixel for illustrating the operation of the display device 10 of FIG. 5 in the emission period P5 of FIG. 6.

As shown in FIG. 6, in the emission period P5, the fourth gate signal EMB and the emission signal EM may each have the active level. On the other hand, in the emission period P5, the first gate signal GW, the second gate signal GR, and the third gate signal GI may each have the inactive level.

The fourth gate signal EMB at the active level may be applied to the gate electrode of the sixth transistor T6 and the gate electrode of the seventh transistor T7 through the fourth gate line EMBL. Accordingly, each of the sixth transistor T6 and the seventh transistor T7 may be turned on.

The emission signal EM at the active level may be applied to the gate electrode of the fifth transistor T5 through the emission line EML. Accordingly, the fifth transistor T5 may be turned on.

The first gate signal GW at the inactive level may be applied to the gate electrode of the second transistor T2 through the first gate line GWL. Accordingly, the second transistor T2 may be turned off.

The second gate signal GR at the non-active level may be applied to the gate electrode of the third transistor T3 through the second gate line GRL. Accordingly, the third transistor T3 may be turned off.

The third gate signal GI at the inactive level may be applied to the gate electrode of the fourth transistor T4 through the third gate line GIL. Accordingly, the fourth transistor T4 may be turned off.

Since the both ends of the capacitor Cst are connected to the first node N1 and the second node N2 by the turned-on seventh transistor T7 in the emission period P5, the first transistor T1 may remain turned on by the gate-source voltage held by the capacitor Cst. For example, in the emission period P5, the voltage of the gate electrode (e.g., first node N1) of the first transistor T1 may have the level of Vdt−((Vref−Vth)−Vint)+(VEL−Vint), and the voltage of the source electrode (e.g., second node N2) of the first transistor T1 may have the level of VEL. The VEL may be a voltage (hereinafter referred to as the emission voltage) applied to the second node N2 through the turned-on first transistor T1. The emission voltage VEL may be based on the driving voltage ELVDD. For example, the emission voltage VEL may be the difference voltage (ELVDD−Vds) between the driving voltage ELVDD and the drain-source voltage (e.g., voltage Vds) of the first transistor T1.

On the other hand, in the emission period P5, as each of the first transistor T1, the fifth transistor T5 and the sixth transistor T6 is turned on, the driving current may be provided to the light-emitting element ED through the first transistor T1, the fifth transistor T5 and the sixth transistor T6 which are turned on. Therefore, the light-emitting element ED may emit light in proportional to the driving current. Since the gate-source voltage held by the capacitor Cst includes the threshold voltage Vth of the first transistor T1, the magnitude of the driving current flowing to the light-emitting element ED through the turned-on first transistor T1 may be determined based on the data voltage Vdt and the threshold voltage Vth of the first transistor T1. Accordingly, the driving current provided to the light-emitting element ED may accurately reflect the level of the data voltage Vdt. In other words, the above-described driving current may have an accurate value with the compensated threshold voltage Vth of the first transistor T1. In this way, different threshold voltages Vth of the first transistors T1 of difference pixels PX may be compensated and the driving currents of the pixels PX may be determined, so that it is possible to reduce the luminance deviations between the pixels PX according to the deviations of the threshold voltages Vth of the first transistors T1 of the pixels PX. In this manner, the image quality of the display device 10 can be improved.

According to an embodiment, the capacitor Cst and the seventh transistor T7 may be connected in series between the gate electrode (e.g., first node N1) and the source electrode (e.g., second node N2) of the driving transistor (e.g., first transistor T1), and thus the connection between the source electrode of the driving transistor and the capacitor Cst may be controlled by the operation of the seventh transistor T7. Accordingly, in the data write period P3, the connection between the source electrode of the driving transistor and the capacitor Cst may be selectively blocked, and thus it is possible to prevent the voltage of the source node from increasing due to the input of the data voltage Vdt and the coupling of the capacitor Cst in the data write period P3. Therefore, the gate-source voltage of the driving transistor may increase in the data write period P3, and thus the range of the data voltage may be extended. Accordingly, the display device according to the embodiment may precisely express grayscales.

According to an embodiment, since the source electrode of the driving transistor is connected to a capacitor Cst, in case that the data voltage Vdt is input during the data write period P3, the voltage of the source electrode may have a more extended range of the data voltage compared to the structure in which it is determined by the capacity ratio between capacitors.

According to an embodiment, since the capacitor Cst is not connected to the driving voltage line VDL, it is possible to improve the issue of voltage instability of the source electrode due to a voltage drop (IR drop) of the driving voltage ELVDD.

According to an embodiment, only one capacitor Cst is used, and it is advantageous in utilizing the area of the pixel PX.

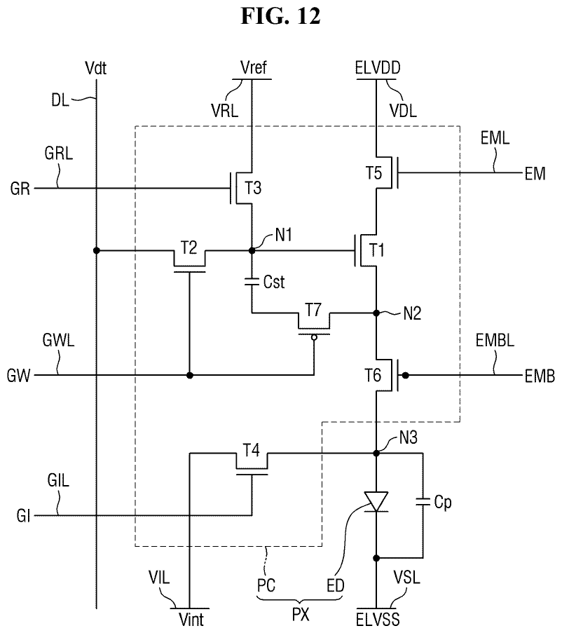

FIG. 12 is a schematic diagram of an equivalent circuit of a pixel of a display device according to an embodiment of the disclosure.

A pixel PX of a display device 10 of FIG. 12 may be different from the pixel PX of the display device 10 of FIG. 5 in line connections. The following description will focus on the difference.

A seventh transistor T7 in FIG. 12 and at least one of the first to sixth transistors T1 to T6 may be of a different type. For example, the seventh transistor T7 and the second transistor T2 may be different types. According to an embodiment of the disclosure, the first to sixth transistors T1 to T6 may be n-type transistors each including an oxide-based active layer, and the seventh transistor T7 may be a p-type transistor including an oxide-based active layer.

The seventh transistor T7 of p-type may be controlled by the first gate signal GW, and the seventh transistor T7 may be connected between the second electrode of the capacitor Cst and the second node N2. The seventh transistor T7 may be turned on by the first gate signal GW of the first gate line GWL to electrically connect the second electrode of the capacitor Cst with the second node N2. The gate electrode of the seventh transistor T7 may be electrically connected to the first gate line GWL, the drain electrode of the seventh transistor T7 may be electrically connected to the second electrode of the capacitor Cst, and the source electrode of the seventh transistor T7 may be electrically connected to the second node N2.

According to an embodiment, the first to seventh transistors T1 to T7 of the pixel PX shown in FIG. 12 may be controlled by the first gate signal GW, the second gate signal GR, the third gate signal GI, the fourth gate signal EMB and the emission signal EM of FIG. 6.

The pixel PX of FIG. 12 may operate based on the first initialization period P1, the threshold voltage detection period P2, the data write period P3, the second initialization period P4, and the emission period P5 as described above.

The operations of the pixel PX of FIG. 12 in the periods P1, P2, P3, P4 and P5 may be substantially identical to the operations of the pixel of FIG. 5 in the periods P1, P2, P3, P4 and P5 described above; and, therefore, the redundant descriptions will be omitted However, the seventh transistor T7 in FIG. 12 may remain turned on during the periods P1, P2, P4 and P5 excluding the data write period P3. For example, the seventh transistor T7 in FIG. 12 may remain turn on during the first initialization period P1, the threshold voltage detection period P2, the second initialization period P4 and the emission period P5, and may remain turned off during the data write period P3.

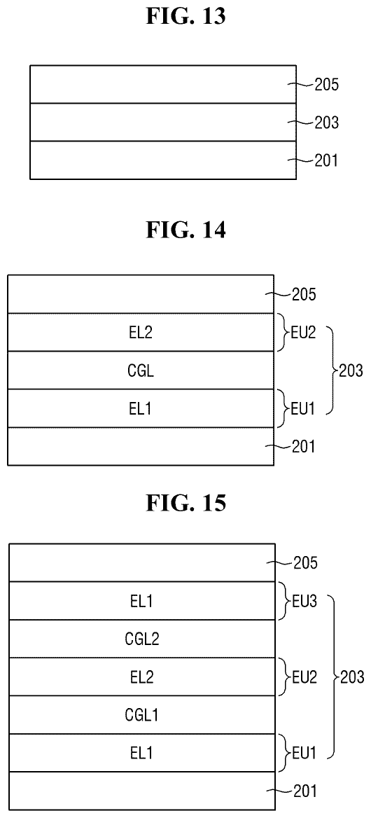

In an embodiment, the above-described light-emitting element ED may have a tandem structure, which will be described below with reference to FIGS. 13 to 20.

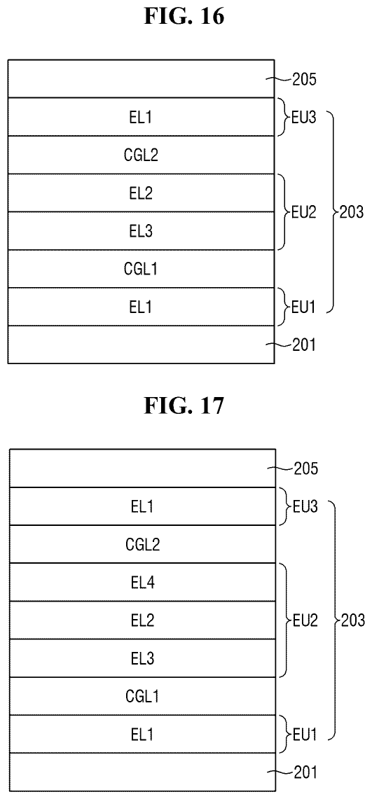

FIG. 13 is a schematic cross-sectional view showing a structure of a display element according to an embodiment of the disclosure. FIGS. 14 to 17 are schematic cross-sectional views illustrating structures of light-emitting elements according to embodiments.

Referring to FIG. 13, a light-emitting element (e.g., an organic light-emitting diode) according to an embodiment may include a pixel electrode 201, a common electrode 205, and an intermediate layer 203 between the pixel electrode 201 and the common electrode 205.

The pixel electrode 201 may include a transparent conductive oxide such as indium tin oxide (ITO), indium zinc oxide (IZO), zinc oxide (ZnO), indium oxide (In₂O₃), indium gallium oxide (IGO) and aluminum zinc oxide (AZO). The pixel electrode 201 may include a reflective layer including silver (Ag), magnesium (Mg), aluminum (Al), platinum (Pt), palladium (Pd), gold (Au), nickel (Ni), neodymium (Nd), iridium (Ir), chrome (Cr) or a compound thereof. For example, the pixel electrode 201 may have a three-layer structure of ITO/Ag/ITO.

The common electrode 205 may be disposed on the intermediate layer 203. The common electrode 205 may include a material having a low work function, an alloy, an electrically conductive compound, or a combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or a combination thereof. The common electrode 205 may be a transmissive electrode, a transflective electrode, or a reflective electrode.

The intermediate layer 203 may include a polymer or a low molecular weight organic material that emits light of a color. In an embodiment, the intermediate layer 203 may further include a metal-containing compound such as an organometallic compound, an inorganic material such as quantum dots, etc.

According to an embodiment, the intermediate layer 203 may include an emissive layer and a first functional layer and a second functional layer respectively disposed under and on the emissive layer. The first functional layer may include, for example, a hole transport layer HTL or may include a hole transport layer and a hole injection layer HIL. The second functional layer may be an optional element disposed on the emissive layer. For example, the intermediate layer 203 may or may not include the second functional layer. The second functional layer may include an electron transport layer ETL and/or an electron injection layer EIL.

According to an embodiment, the intermediate layer 203 may include two or more emitting units sequentially stacked between the pixel electrode 201 and the common electrode 205, and a charge generation layer CGL disposed between the two adjacent emitting units. In case that the intermediate layer 203 includes the emitting units and the charge generation layer, the light-emitting element (e.g., organic light-emitting diode) may have a tandem structure. The light-emitting element (e.g., an organic light-emitting diode) may improve the color purity and the emission efficiency by employing a stack structure of multiple emitting units.

One emitting unit may include an emissive layer, and a first functional layer and a second functional layer respectively disposed under and on the emissive layer. The charge generation layer CGL may include a negative charge generation layer and a positive charge generation layer. The emission efficiency of an organic light-emitting diode, which is a tandem light-emitting element having multiple emissive layers, may be further increased by the negative charge generating layer and the positive charge generating layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

According to an embodiment, as shown in FIG. 14, the light-emitting element (e.g., an organic light-emitting diode) may include a first emitting unit EU1 including a first emissive layer EL1 and a second emitting unit EU2 including a second emissive layer EL2 stacked on each other. The charge generation layer CGL may be disposed between the first emitting unit EU1 and the second emitting unit EU2. For example, the light-emitting element (e.g., an organic light-emitting diode) may include a pixel electrode 201, a first emissive layer EL1, a charge generation layer CGL, a second emissive layer EL2, and a common electrode 205 sequentially stacked on one another. A first functional layer and a second functional layer may be disposed under and on the first emissive layer EL1, respectively. A first functional layer and a second functional layer may be disposed under and on the second emissive layer EL2, respectively. The first emissive layer EL1 may be a blue emissive layer, and the second emissive layer EL2 may be a yellow emissive layer.

According to an embodiment, as shown in FIG. 15, the light-emitting element (e.g., an organic light-emitting diode) may include a first emitting unit EU1 including a first emissive layer EL1, a third light-emitting unit EU3 including a first emissive layer EL1, and a second emitting unit EU2 including a second emissive layer EL2. The first charge generation layer CGL1 may be disposed between the first emitting unit EU1 and the second emitting unit EU2, and the second charge generation layer CGL2 may be disposed between the second emitting unit EU2 and the third emitting unit EU3. For example, the light-emitting element (e.g., organic light-emitting diode) may include a pixel electrode 201, a first emissive layer EL1, a first charge generation layer CGL1, a second emissive layer EL2, a second charge generation layer CGL2, a first emissive layer EL1, and a common electrode 205, which are stacked on one another in this order. A first functional layer and a second functional layer may be disposed under and on the first emissive layer EL1, respectively. A first functional layer and a second functional layer may be disposed under and on the second emissive layer EL2, respectively. The first emissive layer EL1 may be a blue emissive layer, and the second emissive layer EL2 may be a yellow emissive layer.

According to an embodiment of the disclosure, the second emitting unit EU2 of the light-emitting clement (e.g., organic light-emitting diode) may further include a third emitting layer EL3 and/or a fourth emitting layer EL4 in direct contact with the second emitting unit EU2 under and/or on the second emitting layer EL2 in addition to the second emitting layer EL2. As used herein, the phrase that the third emitting layer EL3 and/or the fourth emitting layer ELA are in direct contact with the second emitting unit EU2 means that no other layer is disposed between the second emitting layer EL2 and the third emitting layer EL3 and/or between the second emitting layer EL2 and the fourth emitting layer EL4. The third emissive layer EL3 may be a red emissive layer, and the fourth emissive layer EL4 may be a green emissive layer.

For example, as shown in FIG. 16, the light-emitting element (e.g., organic light-emitting diode) may include a pixel electrode 201, a first emissive layer EL1, a first charge generation layer CGL1, a third emissive layer EL3, a second emissive layer EL2, a second charge generation layer CGL2, a first emissive layer EL1, and a common electrode 205, which are stacked on one another in this order. In another embodiment, as shown in FIG. 17, the light-emitting element (e.g., organic light-emitting diode) may include a pixel electrode 201, a first emissive layer EL1, a first charge generation layer CGL1, a third emissive layer EL3, a second emissive layer EL2, a fourth emissive layer EL4, a second charge generation layer CGL2, a first emissive layer EL1, and a common electrode 205, which are stacked on one another in this order.

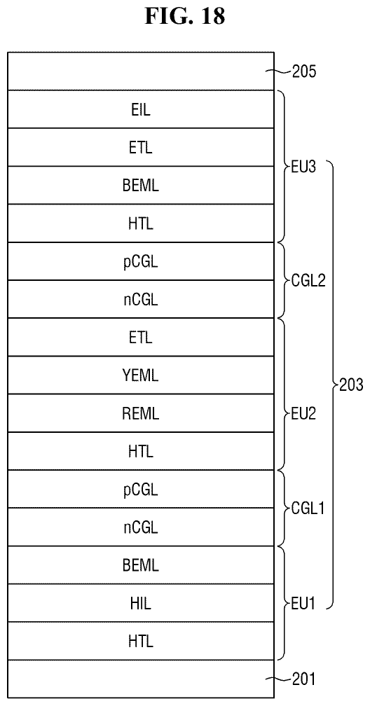

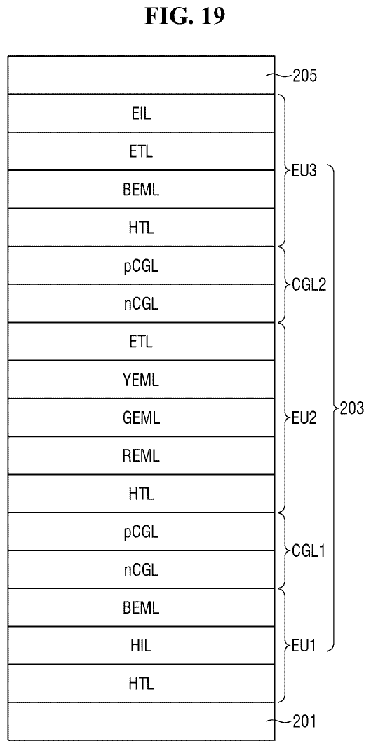

FIG. 18 is a schematic cross-sectional view showing an embodiment of the organic light-emitting diode of FIG. 16. FIG. 19 is a schematic cross-sectional view showing an embodiment of the organic light-emitting diode of FIG. 17.

Referring to FIG. 18, the light-emitting element (e.g., an organic light-emitting diode) may include a first emitting unit EU1, a second emitting unit EU2, and a third emitting unit EU3 stacked on one another in this order. The first charge generation layer CGL1 may be disposed between the first emitting unit EU1 and the second emitting unit EU2, and the second charge generation layer CGL2 may be disposed between the second emitting unit EU2 and the third emitting unit EU3. Each of the first charge generation layer CGL1 and the second charge generation layer CGL2 may include a negative charge generation layer nCGL and a positive charge generation layer pCGL.

The first emitting unit EU1 may include a blue emissive layer BEML. The first emitting unit EU1 may further include a hole injection layer HIL and a hole transport layer HTL between the pixel electrode 201 and the blue emissive layer BEML. According to an embodiment of the disclosure, a p-doped layer may be further included between the hole injection layer HIL and the hole transport layer HTL. The p-doped layer may be formed by doping the hole injection layer HIL with a p-type doping material. According to an embodiment of the disclosure, at least one of a blue light auxiliary layer, an electron blocking layer and a buffer layer may be further included between the blue emissive layer BEML and the hole transport layer HTL. The blue light auxiliary layer may increase the emission efficiency of the blue emissive layer BEML. The blue light auxiliary layer may increase the emission efficiency of the blue emissive layer BEML by adjusting the hole charge balance. The electron blocking layer may be used to prevent injection of electrons into the hole transport layer HTL. The buffer layer may be used to compensate for a resonance distance according to a wavelength of light emitted from the emissive layer.

The second emitting unit EU2 may include a yellow emissive layer YEML and a red emissive layer REML directly in contact with the yellow emissive layer YEML under the yellow emissive layer YEML. The second emitting unit EU2 may further include a hole transport layer HTL between the positive charge generation layer pCGL of the first charge generation layer CGL1 and the red emissive layer REML, and an electron transport layer ETL between the yellow emissive layer YEML and the negative charge generation layer nCGL of the second charge generation layer CGL2.

The third emitting unit EU3 may include a blue emissive layer BEML. The third emitting unit EU3 may further include a hole transport layer HTL between the positive charge generation layer pCGL of the second charge generation layer CGL2 and the blue emissive layer BEML. The third emitting unit EU3 may further include an electron transport layer ETL and an electron injection layer EIL between the blue emissive layer BEML and the common electrode 205. The electron transport layer ETL may be made up of a single layer or multiple layers. According to an embodiment of the disclosure, at least one of a blue light auxiliary layer, an electron blocking layer and a buffer layer may be further included between the blue emissive layer BEML and the hole transport layer HTL. At least one of the hole blocking layer and the buffer layer may be further included between the blue emissive layer BEML and the electron transport layer ETL. The hole blocking layer may be used to prevent injection of holes into the electron transport layer ETL.

The light-emitting element (e.g., organic light-emitting diode) shown in FIG. 19 may be substantially identical to the light-emitting clement (e.g., organic light-emitting diode) shown in FIG. 17 except for a stack structure of a second emitting unit EU2. Referring to FIG. 19, the second emitting unit EU2 may include a yellow emissive layer YEML; a green emissive layer GEML directly in contact with the yellow emissive layer YEML under the yellow emissive layer YEML; and a red emissive layer REML directly in contact with the green emissive layer GEML on the green emissive layer GEML. The second emitting unit EU2 may further include a hole transport layer HTL between the positive charge generation layer pCGL of the first charge generation layer CGL1 and the red emissive layer REML, and an electron transport layer ETL between the yellow emissive layer YEML and the negative charge generation layer nCGL of the second charge generation layer CGL2.

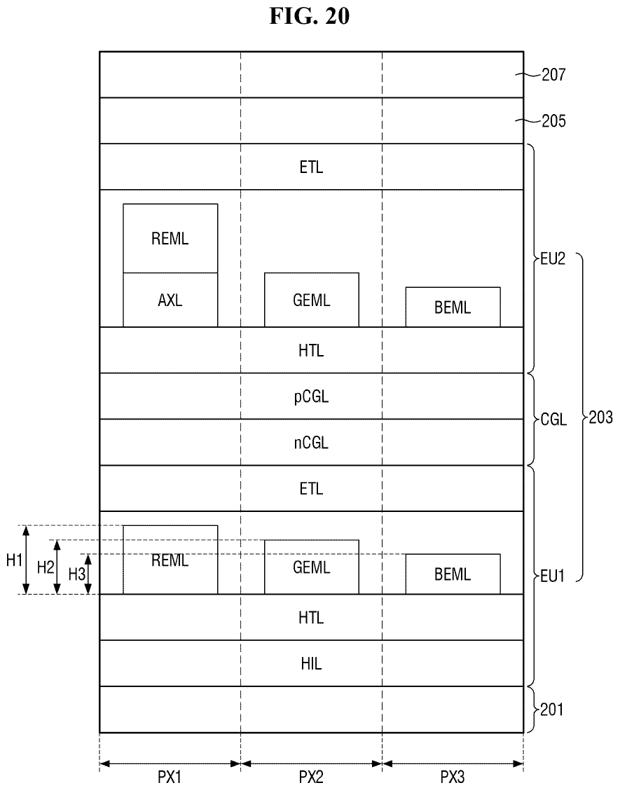

FIG. 20 is a schematic cross-sectional view illustrating a structure of a pixel of a display device according to an embodiment of the disclosure.

Referring to FIG. 20, a display panel 100 of a display device 10 may include multiple pixels. The pixels may include a first pixel PX1, a second pixel PX2 and a third pixel PX3. Each of the first pixel PX1, the second pixel PX2 and the third pixel PX3 may include a pixel electrode 201, a common electrode 205 and an intermediate layer 203. According to an embodiment of the disclosure, the first pixels PX1 may be red pixels, the second pixels PX2 may be green pixels, and the third color pixels PX3 may be blue pixels.

The pixel electrode 201 may be independently disposed in each of the first pixel PX1, the second pixel PX2 and the third pixel PX3.

The intermediate layer 203 of each of the first pixel PX1, the second pixel PX2 and the third pixel PX3 may include a first emitting unit EU1, a second emitting unit EU2, and a charge generation layer CGL between the first emitting unit EU1 and the second emitting unit EU2, which are stacked on one another. The charge generation layers CGL may include negative charge generation layer nCGL and positive charge generation layer pCGL. The charge generation layer CGL may be a common layer continuously formed across the first pixel PX1, the second pixel PX2 and the third pixel PX3.

The first emitting unit EU1 of the first pixel PX1 may include a hole injection layer HIL, a hole transport layer HTL, a red emissive layer REML, and an electron transport layer ETL sequentially stacked on the pixel electrode 201. The first emitting unit EU1 of the second pixel PX2 may include a hole injection layer HIL, a hole transport layer HTL, a green emissive layer GEML, and an electron transport layer ETL sequentially stacked on the pixel electrode 201. The first emitting unit EU1 of the third pixel PX3 may include a hole injection layer HIL, a hole transport layer HTL, a blue emissive layer BEML, and an electron transport layer ETL sequentially stacked on the pixel electrode 201. Each of the hole injection layer HIL, the hole transport layer HTL and the electron transport layer ETL of the first emitting units EU1 may be a common layer extended across the first pixel PX1, the second pixel PX2 and the third pixel PX3.

The second emitting unit EU2 of the first pixel PX1 may include a hole transport layer HTL, an auxiliary layer AXL, a red emissive layer REML, and an electron transport layer ETL sequentially stacked on the charge generation layer CGL. The second emitting unit EU2 of the second pixel PX1 may include a hole transport layer HTL, a green emissive layer GEML, and an electron transport layer ETL sequentially stacked on the charge generation layer CGL. The second emitting unit EU2 of the third pixel PX3 may include a hole transport layer HTL, a blue emissive layer BEML, and an electron transport layer ETL sequentially stacked on the charge generation layer CGL. Each of the hole transport layer HTL and the electron transport layer ETL of the second emitting units EU2 may be a common layer extended across the first pixel PX1, the second pixel PX2 and the third pixel PX3. According to an embodiment of the disclosure, at least one of a hole blocking layer and a buffer layer may be further disposed between the emissive layer and the electron transport layer ETL in the second emitting units EU2 of the first pixel PX1, the second pixel PX2 and the third pixel PX3.

A thickness H1 of the red emissive layer REML, a thickness H2 of the green emissive layer GEML, and a thickness H3 of the blue emissive layer BEML may be determined depending on the resonance distance. The auxiliary layer AXL may be additionally disposed to adjust the resonance distance and may include a material for adjusting resonance. For example, the auxiliary layer AXL and the hole transport layer HTL may include a same material.

Although the auxiliary layer AXL is disposed only in the first pixel PX1 in the example shown in FIG. 20, the disclosure is not limited thereto. For example, the auxiliary layer AXL may be disposed in at least one of the first pixel PX1, the second pixel PX2 and the third pixel PX3 in order to match the resonance distance of each of the first pixel PX1, the second pixel PX2 and the third pixel PX3.

The display panel 100 of the display device 10 may further include a capping layer 207 disposed on the common electrode 205. The capping layer 207 may be used to improve the emission efficiency by the principle of constructive interference. Accordingly, the out-coupling efficiency of the light-emitting element (e.g., organic light-emitting diode) may be increased, and thus the emission efficiency of the light-emitting element (e.g., organic light-emitting diode) may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a light-emitting element;
a first transistor connected between a driving voltage line and the light-emitting element;
a capacitor connected between a gate electrode and a source electrode of the first transistor; and
a second transistor connected between the capacitor and the source electrode of the first transistor,
wherein the capacitor and the second transistor are connected in series between the gate electrode of the first transistor and the source electrode of the first transistor.

2. The display device of claim 1, further comprising:
a third transistor connected between a data line and the gate electrode of the first transistor.

3. The display device of claim 2, further comprising:
a fourth transistor connected between a reference voltage line and the gate electrode of the first transistor.

4. The display device of claim 3, further comprising:
a fifth transistor connected between an initialization voltage line and an anode electrode of the light-emitting element.

5. The display device of claim 4, further comprising:
a sixth transistor connected between the driving voltage line and a drain electrode of the first transistor.

6. The display device of claim 5, further comprising:
a seventh transistor connected between the source electrode of the first transistor and the anode electrode of the light-emitting element.

7. The display device of claim 6, further comprising:
a first gate line connected to a gate electrode of the third transistor;
a second gate line connected to a gate electrode of the fourth transistor;
a third gate line connected to a gate electrode of the fifth transistor;
an emission line connected to a gate electrode of the sixth transistor; and
a fourth gate line connected to a gate electrode of the seventh transistor and a gate electrode of the second transistor.

8. The display device of claim 7, wherein
the data line transmits a data voltage,
the first gate line transmits a first gate signal,
the second gate line transmits a second gate signal,
the third gate line transmits a third gate signal,
the fourth gate line transmits a fourth gate signal, and
the emission line transmits an emission signal.

9. The display device of claim 8, wherein in a first initialization period,
each of the third gate signal and the fourth gate signal has an active level, and
each of the first gate signal, the second gate signal and the emission signal has an inactive level.

10. The display device of claim 9, wherein in a threshold voltage detection period after the first initialization period,
each of the second gate signal and the emission signal has the active level, and
each of the first gate signal, the third gate signal and the fourth gate signal has the inactive level.

11. The display device of claim 10, wherein in a data write period after the threshold voltage detection period,
the first gate signal has the active level,
each of the second gate signal, the third gate signal, the fourth gate signal and the emission signal has the inactive level, and
the data voltage is applied to the data line.

12. The display device of claim 11, wherein in a second initialization period after the data write period,
each of the third gate signal and the fourth gate signal has the active level, and each of the first gate signal, the second gate signal and the emission signal has the inactive level.

13. The display device of claim 12, wherein in an emission period after the second initialization period,
each of the fourth gate signal and the emission signal has the active level, and
each of the first gate signal, the second gate signal and the third gate signal has the inactive level.

14. The display device of claim 13, wherein each of the first to seventh transistors is an n-type transistor.

15. The display device of claim 13, wherein a type of the second transistor and a type of at least one of the first transistor, the third transistor, the fourth transistor, the fifth transistor, the sixth transistor, and the seventh transistor are different.

16. The display device of claim 15, wherein the type of the second transistor and the type of the third transistor are different.

17. The display device of claim 15, wherein
each of the first transistor, the third transistor, the fourth transistor, the fifth transistor, the sixth transistor, and the seventh transistor is an n-type transistor, and
the second transistor is a p-type transistor.

18. The display device of claim 6, further comprising:
a first gate line connected to a gate electrode of the third transistor and the second transistor;
a second gate line connected to a gate electrode of the fourth transistor;
a third gate line connected to a gate electrode of the fifth transistor;
an emission line connected to a gate electrode of the sixth transistor; and
a fourth gate line connected to a gate electrode of the seventh transistor.

19. The display device of claim 18, wherein the gate electrode of the second transistor and the gate electrode of the third transistor are connected to the first gate line.

20. The display device of claim 6, wherein each of the first to seventh transistors comprises an oxide-based active layer.
